(19) United States
(12) Patent Application Publication
(10) Pub. No.: US 2023/0179165 A1
(43) Pub. Date: Jun. 8, 2023

(54) METHOD FOR FORMING A LAYER WITH THE BASIC OF A PIEZOELECRIC MATERIAL AND SURFACE ACOUSTIC WAVE DEVICE USING SUCH A LAYER

(71) Applicant: COMMISSARIAT A L'ENERGIE ATOMIQUE ET AUX ENERGIES ALTERNATIVES, Paris (FR)

(72) Inventors: Florian DUPONT, Grenoble Cedex 09 (FR); Guillaume RODRIGUEZ, Grenoble Cedex 09 (FR); Laura SAUZE, Grenoble Cedex 09 (FR)

(73) Assignee: COMMISSARIAT A L'ENERGIE ATOMIQUE ET AUX ENERGIES ALTERNATIVES, Paris (FR)

(21) Appl. No.: 18/061,774

(22) Filed: Dec. 5, 2022

(30) Foreign Application Priority Data
Dec. 6, 2021 (FR) 21 13025

(51) Int. Cl. H03H 3/08; H03H 9/02; H03H 9/25; C30B 29/40; C30B 29/30; C30B 29/68; C30B 23/02; C30B 23/06

(52) U.S. Cl. CPC H03H 3/08; H03H 9/02559; H03H 9/02834; H03H 9/25; C30B 29/403; C30B 29/30; C30B 29/68; C30B 23/025; C30B 23/066

(57) ABSTRACT

A method for forming a lithium niobate- or lithium tantalum-based (LN/LT) layer includes providing a silicon-based substrate, forming nucleation layer on the substrate, and forming the LN/LT layer by epitaxy on the nucleation layer. The nucleation layer is chosen based upon a III-N material. The nucleation layer may be used in a surface acoustic wave device.

### TECHNICAL FIELD

The present invention generally relates to a surface acoustic wave device, and more specifically, a method for producing the layer with the basis of a piezoelectric material forming the core of this device.

### STATE OF THE ART

Resonators based on a so-called SAW (Surface Acoustic Wave)-type structure are historically used to produce RF filters. The core of SAW resonators is composed of a piezoelectric material which impacts the final properties of the filter.

Lithium niobate (LiNbO3) has been used for a few years as piezoelectric in material. Its intrinsic properties, like its piezoelectric coupling coefficient, could enable the filter to resonate at high frequency, for example at frequencies greater than 5 GHz. However, the thin layer synthesis of this material is complex and the requirements linked to its quality are high. The thin LiNbO3 layer must, in particular, have a high crystalline quality and a controlled stoichiometry. It must also have a controlled crystalline orientation and making it possible to maximise the propagation speed of the waves.

Solutions making it possible to synthesise LiNbO3 in thin layers on a sapphire substrate have been developed. The applications linked to these solutions however remain limited. The production of thin LiNbO3 layers on a silicon-based substrate has a considerable challenge. This would make it possible to consider a new generation of multifunctional devices comprising electrooptic, acoustic, microelectronic and/or energy recovery devices cointegrated on one same substrate. A solution consists of extending a thin LiNbO3 layer from a donor substrate, typically from a monocrystalline LiNbO3 substrate, to a receiver substrate, typically a silicon substrate with a superficial oxide layer. This solution implementing numerous technical steps has a significant cost. The achievable range of thin layer thicknesses, typically greater than 200 nm, is also limited by technical extending constraints.

Document U.S. Pat. No. 7,005,947 B2 proposes another solution consisting to forming a buffer layer with the basis of a rare earth oxide on the silicon-based substrate, before subjecting a lithium niobate-based layer to epitaxy. This solution is however complex to implement. The cost of manufacturing such a layer remains high. With a view to cointegrate, the compatibility of this method must also be improved.

There is therefore a need consisting of producing a lithium niobate-based layer on a silicon-based substrate, which has a crystalline quality which is compatible with the targeted applications, while limiting the production costs.

An aim of the present invention is to at least partially meet this need.

In particular, an aim of the present invention is to propose a method for forming a lithium niobate layer on silicon substrate, which has an optimised cost/compatibility vs-à-vis the current methods.

Another aim of the present invention is to propose a device typically a surface acoustic wave device, benefiting from such a lithium niobate layer.

Other aims, features and advantages of the present invention will appear upon examining the following description and the accompanying drawings. It is understood that other advantages can be incorporated.

### SUMMARY

To achieve this aim, according to an embodiment, a method for forming a so-called LN/LT layer is provided, with the basis of an ABO3-type material, O being oxygen. A being at least one first chemical element taken from among sodium (Na), potassium (K), barium (Ba), lithium (Li), lead (Pb), and B being at least one second chemical element taken from among zirconium (Zr), titanium (Ti), niobium (Nb), tantalum (Ta), the method comprising the following steps:
Providing a silicon-based substrate, preferably crystalline, preferably oriented along (111),
Forming a nucleation layer on the substrate,
Forming the LN/LT layer on the nucleation layer by epitaxy.

Advantageously, the nucleation layer is chosen from a nitride-based refractory material.

In the scope of development of the present invention, specifications for the nucleation layer has been established. The nucleation layer must preferably have the following properties:
Having a crystalline structure and/or a mesh parameter compatible with a silicon-based substrate. This makes it possible, for example, to subject the nucleation layer to epitaxy on the substrate.
Having a crystalline structure and/or a mesh parameter close to or compatible with lithium niobate or lithium tantalum. This makes it possible to subject the LN/LT layer to epitaxy on the nucleation layer.
Having a thermal dilatation coefficient close to lithium niobate or lithium tantalum. This makes it possible to limit the appearance of cracks due to temperature variations during the formation of the LN/LT layer.
Being able to block the diffusion of Li atoms in Si. This makes it possible to avoid a loss of stoichiometry of the LN/LT layer.
Confining an acoustic wave, in particular in view of guaranteeing high performances for electroacoustic devices.

A technical prejudice of the state of the art is that such a nucleation layer must necessarily be oxide-based, in order to avoid a loss of stoichiometry of the LN/LT layer due to a diffusion of oxygen from the LN/LT layer to the nucleation layer.

On the contrary, to meet these specifications, the nucleation layer is chosen according to the present invention made of a nitride-based refractory material. This nucleation layer made of a nitride-based refractory material is called refractory nitride-based nucleation layer below, to be concise. in the scope of the development of the present invention, it has indeed been observed that such a refractory nitride-based nucleation layer enables, fully unexpectedly, the epitaxy of the LN/LT layer under good conditions. Surprisingly, it has also been observed that such a nucleation layer makes it possible to block both the diffusion of oxygen and the diffusion of lithium to the silicon-based substrate. This results in the LN/LT layer subjected to epitaxy on such a nucleation layer preserving the required stoichiometry.

Moreover, the different crystalline structures and the mesh parameters of refractory nitrides, typically the nitrides III-N, are fully compatible with those made of LN/LT materials and silicon. Such a nucleation layer can therefore advantageously be subjected to epitaxy on a silicon-based substrate, then enable the epitaxy of the LN/LT layer.

The present invention thus proposes a solution making it possible to synthesise a thin LN/LT layer directly on a silicon-based substate—i.e. without an extending step—by way of the refractory nitride-based nucleation layer. Thanks to the refractory nitride-based nucleation layer, this LN/LT layer is stoichiometric and of high crystalline quality. The refractory nitride-based nucleation layer further enables a good confinement of the acoustic wave in the LN/LT layer.

The refractory nitride-based nucleation layer thus makes it possible to subject to epitaxy, a thin LN/LT layer having the required properties for a high frequency SAW filter-type application.

According to another aspect of the invention, a surface acoustic wave (SAW) device is provided, comprising, stacked in a vertical direction z:
a silicon-based substrate, preferably crystalline,
a nucleation layer on said substrate,
an LN/LT layer on the nucleation layer, said LN/LT layer being with the basis of an ABO3-type material, O being oxygen, A being at least one first chemical element taken from among sodium (Na), potassium (K), barium (Ba), lithium (Li), lead (Pb), and B being at least one second chemical element taken from among zirconium (Zr), titanium (Ti), niobium (Nb), tantalum (Ta), and
an electrode disposed on the LN/LT layer.

Advantageously, the nucleation layer of the SAW device is with the basis of a refractory nitride. The advantages mentioned above apply mutatis mutandis. Such a device is further directly integrable in silicon technology. It can be easily cointegrated with other microelectronic or optoelectronic devices, or also with (opto-) electromechanical microsystems (MEMS (Microelectromechanical systems) or MOMS (Microoptoelectromechanical systems)).

The LN/LT layer is with the basis of the ABO3 material, preferably LiNbO3- or LiTaO3-based, or of a Li(Nb,Ta)O3 mixture, or also (KNa)NbO3-based.

### BRIEF DESCRIPTION OF THE FIGURES

The aims, objectives, as well as the features and advantages of the invention will best emerge from the detailed description of embodiments of the latter, which are illustrated by the following accompanying drawings, wherein:

FIG. 1A illustrates, as a transverse cross-section, a device according to an embodiment of the present invention.

FIG. 1B illustrates, as a top view, the device according to the embodiment illustrated in FIG. 1A.

FIG. 2 illustrates, as a transverse cross-section, a device according another embodiment of the present invention.

FIG. 3 illustrates an X-ray diffraction spectrum obtained from an LN/LT layer subjected to epitaxy on an AlN-based nucleation layer according to an embodiment of the present invention.

FIG. 4 illustrates a “rocking curve”-type analysis obtained from an LN/T layer subjected to epitaxy on an AlN-based nucleation layer according to an embodiment of the present invention.

FIG. 5 illustrates a “phi scan”-type analysis obtained from an LN/LT layer subjected to epitaxy on an AlN-based nucleation layer on a silicon substrate according to an embodiment of the present invention.

The drawings are given as examples and are not limiting of the invention. They constitute principle schematic representations intended to facilitate the understanding of the invention, and are not necessarily to the scale of practical applications. In particular, on the principle diagrams, the thicknesses of the different layers and portions, and the dimensions of the patterns are not representative of reality.

### DETAILED DESCRIPTION

Before starting a detailed review of embodiments of the invention, optional features are stated below, which can optionally be used in association or alternatively:

According to an example, the nitride-based refractory material of the nucleation layer is chosen so as to have or to form:
A resistance to oxidation,
A barrier to diffusion of lithium.

This makes it possible to avoid a diffusion of oxygen and of lithium from the LN/LT layer to the nucleation layer. The stoichiometry of the LN/LT layer is thus preserved.

According to an example, the nitride-based refractory material of the nucleation layer is chosen so as to have a sufficiently high hardness or mechanical rigidity to make it possible to confine an acoustic wave in the LN/LT layer. For example, the Young's modulus of this material is greater than 300 GPa. Its hardness or resistance can be greater than 9000 MPa.

According to an example, the nitride-based refractory material of the nucleation layer is chosen so as to have a crystallographic structure compatible with the substrate and the LN/LT layer, such as a hexagonal structure. This makes it possible to limit the appearance of structural defects during the formation of the LN/LT layer by epitaxy. According to an example, the variance in mesh parameter between the nitride-based refractory material and the LN/LT material is less than 2%. This variance in mesh parameter can be taken at a subarray of the normal cell of the LN/LT material. For example, in the case of the LiNbO3 LN/LT material, the mesh parameter of the normal cell is 5.148 Å. In the plane (0001), it is however possible to determine a hexagonal or minicell subarray of 3.056 Å of mesh parameter. According to an example, if the nitride-based refractory material is aluminium nitride AlN which has a mesh parameter of 3.112 Å, the variance in mesh parameter between the LiNbO3 minicell and AlN is around 1.8%. The LiNbO3 epitaxy can be done on AlN, surprisingly. To align the hexagonal AlN arrays and the LiNbO3 minicell, a twist of around 30° between the LiNbO3 arrays and AlN appear typically, in the plane (0001).

According to an example, the ABO3-type material of the LN/LT layer is chosen from among: lithium niobate (LiNbO3), lithium tantalum (LiTaO3), or an Li(Nb,Ta)O3 alloy.

According to an alternative example, the ABO3-type material of the LNILT layer is chosen from among: BaTiO3, Pb(Zr,Ti)O3, (K,Na)NbO3.

According to an example, the formation of the nucleation lever is configured such that said nucleation layer has a thickness e2 less than or equal to 200 nm, preferably less than or equal to 50 nm. This makes it possible to limit the appearance of structural defects during the formation of the nucleation layer by epitaxy.

According to an example, the formation of the LN/LT layer is configured, such that said LN/LT layer has, after epitaxy, a thickness e3 of between 50 nm and 500 nm, for example around 200 nm. Such a thickness e3 corresponds to a thin LN/LT layer. Such a thickness e3 cannot be obtained in practice by extending and thinning a layer from a donor substrate distinct from the receiving substrate.

According to an example, the nitride-based refractory material is taken from among refractory nitrides III-N with the basis of an element of the group III, such as boron nitride BN, aluminium nitride AlN, gallium nitride GaN, indium nitride InN, and their alloys, for example AlGaN, or transition refractory nitrides with the basis of a transition metal, such as titanium nitride TiN, tantalum nitride TaN, niobium nitride NbN, zirconium nitride ZrN, hafnium nitride HfN, vanadium nitride VN.

According to an example, the nitride-based refractory material is a refractory nitride III-N taken from among gallium nitride GaN, aluminium nitride AlN, boron nitride BN, or a nitride alloy III-N, for example an AlGaN alloy.

According to an example, the nitride-based refractory material of the nucleation layer is chosen from among a transition refractory nitride, such as titanium nitride TiN, tantalum nitride TaN, niobium nitride NbN, zirconium nitride ZrN, hafnium nitride HfN, vanadium nitride VN.

According to an example, the formation of the nucleation layer and the formation of the LN/LT layer are carried out by pulsed laser deposition successively within one same reactor without flushing with air between said formations. This makes it possible to avoid an intermediate surface cleaning step, to reduce the total duration of the method and to limit the costs. This also makes it possible to obtain a low surface roughness of the LN/LT layer.

According to an example, the method further comprises a formation of an upper electrode on the LN/LT layer. This makes it possible, in particular, to produce SAW-type electroacoustic devices.

According to an example, the method further comprises a formation of a temperature compensation layer, for example SiO2 based, on the upper electrode and the LN/LT layer. This makes it possible to decrease the variation in frequency of the resonance of the electroacoustic device, typically a resonator or SAW filter, under the effect of temperature.

According to an example, the LN/LT layer is directly in contact with the nucleation layer. In particular, there is no oxide interlayer between the nucleation layer and the LN/LT layer.

According to an example, the nitride-based refractory material of the nucleation layer is a refractory nitride III-N such as aluminium nitride AlN, gallium nitride GaN, boron nitride BN, or a nitride III-N alloy, for example an AlGaN alloy.

According to an example, the nitride-based refractory material of the nucleation layer is a transition refractory nitride such as titanium nitride TiN, tantalum nitride TaN, niobium nitride NbN, zirconium nitride ZrN, hafnium nitride HfN, vanadium nitride VN.

According to an example, the LN/LT layer has a thickness e3 of between 50 nm and 500 nm, for example around 100 nm or 200 nm, such that the device forms a piezoelectric thin layer resonator.

According to an example, the device further comprises, on the upper electrode and the LN/LT layer, a temperature compensation layer, for example SiO2-based. This makes it possible to decrease the variation in frequency of the resonance of the device under the effect of temperature.

According to an example, the silicon-based substrate is formed of a material taken from among silicon, SiC, SiGe.

According to an example, the silicon-based substrate is monocrystalline.

According to an alternative example, the silicon-based substrate is polycrystalline.

According to an example, the silicon-based substrate is oriented along (111).

Unless incompatible, it is understood that all of the optional features above can be combined so as to form an embodiment which is not necessarily illustrated or described. Such an embodiment is obviously not, excluded from the invention. The features of an aspect of the invention, for example the device or the method, can be adapted mutatis mutandis to the other aspect of the invention.

It is specified that, in the scope of the present invention, the terms “on”, “surmounts”, “covers”, “underlying”, “opposite” and their equivalents do not necessarily mean “in contact with”. Thus, for example, the deposition of a first layer on a second layer, does not compulsorily mean that the two layers are directly in contact with one another, but means that the first layer covers at least partially the second layer by being either directly in contact with it, or by being separated from it by at least one other layer or at least one other element.

A layer can moreover be composed of several sublayers of one same material or of different materials.

By a substrate, a stack, a layer “with the basis” of a material A, this means a substrate, a stack, a layer comprising this material A only or this material A and optionally other materials, for example alloy elements and/or doping elements. Thus, a silicon-based substrate means, for example, an Si, doped Si, SiC, SiGe substrate. An in AlN-based layer means, for example, an AlN, doped AlN layer, or AlN alloys, for example AlGaN.

By “selective etching vis-à-vis” or “etching having a selectivity vis-à-vis”, this means an etching configured to remove a material A or a layer A vis-à-vis a material B or a layer B, and having an etching speed of the material A greater than the etching speed of the material B. The selectivity is the ratio between the etching speed of the material A on the etching speed of the material B.

Several embodiments of the invention implementing successive steps of the manufacturing method are described below. Unless explicitly mentioned, the adjective “successive” does not necessarily imply, even if this is generally preferred, that the steps immediately follow one another, intermediate steps could separate them.

Moreover, the term “step” means the performing of some of the method, and can mean a set of substeps.

Moreover, the term “step” does not compulsorily mean that the actions carried out during a step are simultaneous or immediately successive. Certain actions of a first step can, in particular, be followed by actions linked to a different step, and other actions of the first step can then be resumed. Thus, the term “step” does not necessarily mean single and inseparable actions over time and in the sequence of phases of the method.

A preferably orthonormal marker, comprising the axes x, y, z is represented in the accompanying figures. When only one marker is represented on one same set of figures, this marker applies to all the figures of this set.

In the present patent application, the thickness of a layer is taken in a normal direction to the main extension plane of the layer. Thus, a layer typically has a thickness along z. The relative terms “on”, “surmounts”, “under”, “underlying”, “inserted” refer to positions taken in the direction z.

The terms “vertical”, “vertically” refer to a direction along z. The terms “horizontal”, “horizontally”, “lateral”, “laterally” refer to a direction in the plane xy. Unless explicitly mentioned, the thickness, the height and the depth are measured along z.

An element located “in vertical alignment with” or “to the right of” another element means that these two elements are both located on one same line perpendicular to a plane wherein mainly extends a lower or upper face of a substrate, i.e. on one same line oriented vertically in the figures.

In the scope of the present invention, a nitride III-N is a nitride of an element preferably belonging to column IIIa of the periodic table (three valence electrons). This column IIIa groups together the earth elements such as bonon, aluminium, gallium, indium. The nitrides III-N considered in the present invention are, in particular, boron nitride BN, aluminium nitride AlN, gallium nitride GaN, indium nitride InN, and their alloys, for example and in a non-limiting manner, AlGaN, GaInN.

In the scope of the present invention, a transition refractory nitride is a nitride of a is transition metal or transition element (element of which the atoms have an incomplete electronic sublayer d, or which can form cations, of which the electronic sublayer d is incomplete). These elements are grouped together within block d of the periodic table of elements. These are, in particular, the elements Ti, Ta, Nb, Zr, Hf, V. The transition refractory nitrides considered in the present invention are, in particular, titanium nitride TiN, tantalum nitride TaN, niobium nitride NbN, zirconium nitride ZrN, hafnium nitride HfN, vanadium nitride VN.

In the examples described below, the LN/LT layer illustrated is lithium niobate LiNbO3-based. A lithium tantalate LiTaO3 layer or a layer of an Li(Ta,Nb)O3 alloy can be substituted for this lithium niobate LiNbO3 layer in the scope of this invention. Thus, all the features and all the technical effects mentioned regarding LiNbO3 are fully applicable and combinable with an LiTaO3 or Li(Ta,Nb)O3 layer. Other ABO3 materials can be substituted for LiNbO3, in particular BaTiO3, Pb(Zr, Ti)O3, (K,Na)NbO3.

X-ray diffraction analyses, for example in configuration 2θ, or in rotation along and/or Ω (phi-scan and omega-scan), can be carried out so as to determine the crystalline quality of the LN/LT layers and of the nucleation layers, and their epitaxy relationship.

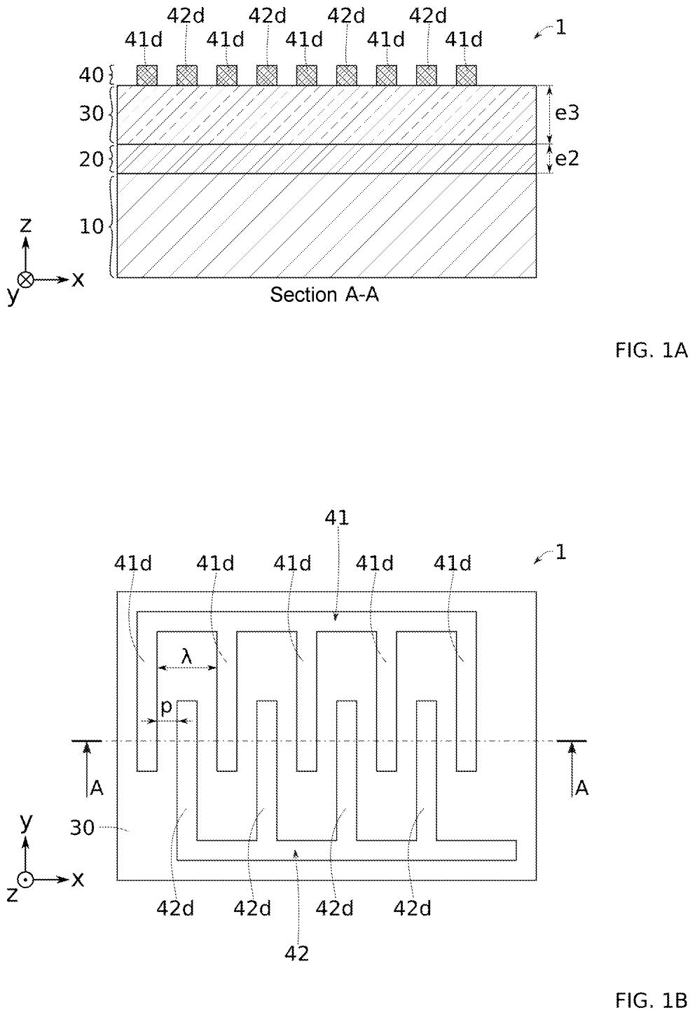

FIGS. 1A and 1B illustrate a first embodiment according to the invention. FIG. 1A illustrates, as a transverse cross-section, a SAW filter-type device 1. This device 1 typically comprises a silicon-based substrate 10 on which is formed an aluminium nitride AlN-based nucleation layer 20. A lithium niobate LiNbO3 layer 30 is directly in contact with the nucleation layer 20. An electrode layer 40, comprising electrode fingers 41d, 42d, surmounts the LN/LT layer 30.

The use of a refractory nitride-based nucleation layer 20, in particular made of AlN, advantageously makes it possible to perform a heteroepitaxy of LiNbO3 on silicon substrate 10. This solution makes it possible to produce devices 1, typically high-performance resonators. The epitaxy makes it possible, in particular, to obtain a stoichiometric LiNbO3 layer, preferably oriented and of high crystalline quality. The thickness of this LiNbO3 layer obtained by epitaxy is further fully controlled. The LiNbO3 layer can be formed directly on substrates 10 of different sizes, without an to intermediate extending step. This advantageously makes it possible to decrease the manufacturing costs of such a stack of layers 10, 20, 30. Such a method further be directly integrated in a production factory with the CMOS technology standard (MOS—transistors—Metal/Oxide/Semiconductor—complementary of N and P type).

The substrate 10 can be a silicon bulk substrate. Alternatively, this substrate 10 is can be an SOI (Silicon On Insulator)-type substrate. Other substrates 10 can be considered, for example SIC-based substrates, SiGe-based substrates. GeOI (Germanium On Insulator) substrates. Such substrates have a total compatibility with silicon technologies for microelectronics. Silicon is further a rigid material making it possible to confine an acoustic wave in an LN/LT-type upper layer, it is also thermally conductive. This makes it possible, for example, to release the heat generated in a SAW filter in operation.

The nucleation layer 20 can be material III-N-based. It preferably has a hexagonal crystallographic structure. Such a material III-N structure enables, in particular, an epitaxy of the nucleation layer on silicon oriented along (001) and (111). This also makes it possible to subject an LN/LT material to epitaxy along different crystalline orientations. Preferably, silicon is oriented along (111). The nucleation layer 20 is, for example, aluminium nitride AlN-based. AlN can be deposited on silicon and its deposition method is advantageously known and understood. Aluminium nitride has a mesh parameter close to lithium niobate. This facilitates the epitaxial growth of lithium niobate. The thermal dilatation coefficient of AlN is further located between that of LiNbO3 and that of Si. This makes it possible to limit the appearance of structural defects in the LN/LT layer during temperature variations linked to the different deposition steps. The melting point of AlN is greater than 2000° C., well above the deposition temperature of LN/LT, which is around 700° C. AlN also has a good resistance to oxidation, and a good resistance to LN/LT deposition methods (resistance to ionised species plasmas and to chemical precursors making it possible to synthesise the LN/LT material). AlN is also sufficiently rigid to enable a good confinement of an acoustic wave. High acoustic performances can thus be obtained for the device 1. AlN can also advantageously serve as an LN/LT etching stop layer. This facilitates the production of thin LN/LT layer electroacoustic devices. This also enables a good dimensional control of the devices. Their acoustic performances are thus improved. Boron nitride and gallium nitride have properties similar to those mentioned above for aluminium nitride. They can also be advantageously chosen for the nucleation layer 20.

The nucleation layer 20 can be formed by a physical or chemical deposition in technique, for example and preferably by pulsed laser deposition PLD. It can be alternatively formed by one of the following techniques: chemical vapour deposition (CVD), preferably metal organic chemical vapour deposition (MOCVD), PVD (sputtering), plasma enhanced atomic layer deposition (PEALD).

It is preferably subjected to epitaxy on the substrate 10. It can be monocrystalline or polycrystalline with, for example, a preferable orientation. An orientation along a growth plane (0001) can be typically chosen for an AlN nucleation layer 20.

The nucleation layer 20 formed on the substrate 10 is preferably stoichiometric. It has a thickness e2 of between 10 and 1000 nanometres, for example around 100 nm. The thickness e2 of the nucleation layer 20 can be chosen according to the desired crystalline quality.

The LN/LT layer 30 is preferably lithium niobate LiNbO3- or lithium tantalum LiTaO3-based, or an Li(Ta,Nb)O3 alloy. This LN/LT layer 30 can be formed by a physical or chemical deposition technique, for example and preferably by pulsed laser deposition PLD. It can be alternatively formed by one of the following techniques: chemical vapour deposition (CVD), preferably metal organic chemical vapour deposition (MOCVD), PVD (sputtering), molecular beam epitaxy (MBE).

The LN/LT layer 30 is subjected to epitaxy on the nucleation layer 20. It can be monocrystalline or polycrystalline, with for example a preferable orientation. An orientation along a growth plane (0001) can be typically chosen. This makes it possible in to maximise the propagation speed of the acoustic waves within the LN/LT layer 30. Other orientations can be chosen according to the desired application.

The LN/LT layer 30 formed on the nucleation layer 20 is preferably stoichiometric, for example Li₁Nb₁O₃. The atomic percentage of lithium is ideally close to 50%, The LN/LT layer 30 has a thickness e3 of between 10 and 2000 nanometres, for example around 200 nm. The thickness e3 of the LN/LT layer 30 can be chosen according to the desired application.

According to a possibility, the nucleation layer 20 and the LN/LT layer 30 are both produced in situ by PLD in one same growth reactor. The growth of the LN/LT layer 30 can thus be produced directly after the end of growth of the nucleation layer 20. This makes it possible to avoid a flushing with air of the nucleation layer 20 before epitaxy of the LN/LT layer 38. The surface of the nucleation layer 20 therefore remains clean. This avoids an intermediate cleaning step. The duration of the method is thus decreased. This also makes it possible to limit the appearance of roughness during the formation of the LN/LT layer 30. The surface state of the latter is thus optimised.

The electrode layer 40 is typically with the basis of an electrically conductive electrode material. According to a possibility, this electrode material can also have a high acoustic impedance. Platinum can be chosen as the electrode material. The electrode layer 48 is typically structured so as to have electrode patterns 41d, 42d. Such an electrode 40 is typically formed by lithography/etching from an electrically conductive layer deposited on the LN/LT layer 30.

FIG. 1B illustrates, as a top view, the device 1. In this example, the upper electrode 40 is presented in the form of two interdigital combs 41, 42. The fingers 41d, 42d of these combs 41, 42 are typically separated by a step p from around a few hundred nanometres to a few microns. The period λ separating two consecutive fingers 41d, 42d of one same comb 41, 42 is typically from around a few hundred nanometres to a few microns. The patterns 41, 41d, 42, 42d of the electrode 40 can have other shapes. The design of these electrode patterns 40 can be adapted as needed.

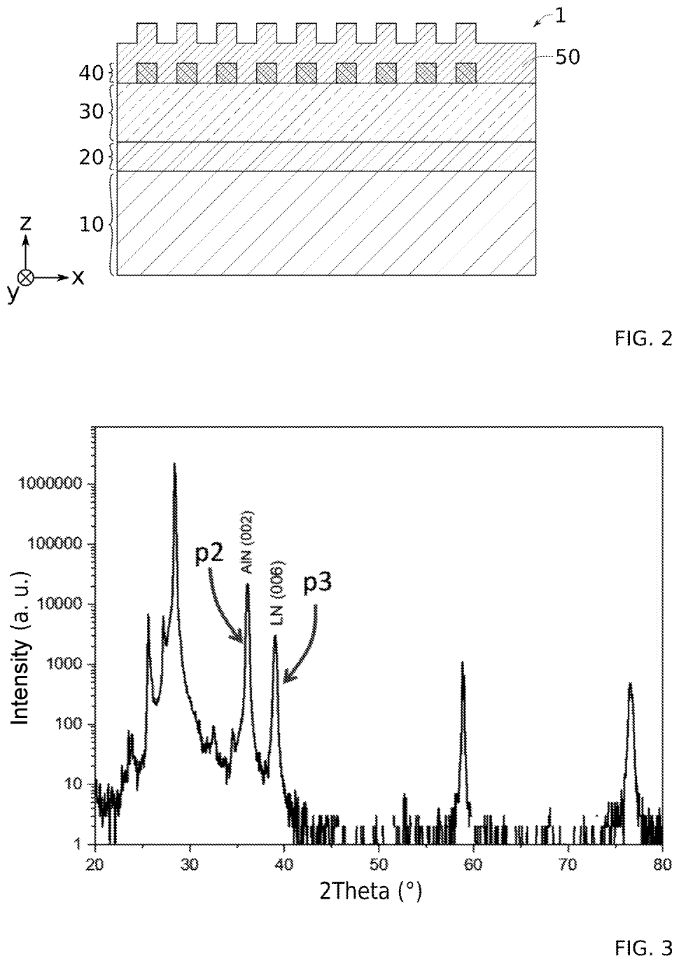

FIG. 2 illustrates another embodiment of the device 1. In this example, a thermal compensation layer 50 is formed above the upper electrode 40. This layer 50 can be formed by conformal deposition on the electrode patterns and between the electrode patterns, on the LN/LT layer 30, as illustrated in FIG. 2. It can be typically deposited by CVD. The thermal compensation layer 58 can be, for example, SiO2-based. It makes it possible, in particular, to decrease the variation in frequency of the resonance of the device 1 under the effect of the temperature. The frequency of the resonance and the bandwidth of the device 1 are thus advantageously stabilised during the use of the device 1.

FIG. 3 illustrates an X-ray diffraction (XRD) symmetrical analysis performed on a stack of layers 10, 20, 30 comprising an AlN nucleation layer and an LN/LT layer made of lithium niobate LiNbO3.

The peak p2 corresponds to stoichiometric AlN and oriented along the plane (002). The peak p3 corresponds to stoichiometric LiNbO3 and oriented along the plane (006). This symmetrical XRD analysis shows that the AlN and LiNbO3 layers obtained by the method according to the invention are stoichiometric and oriented.

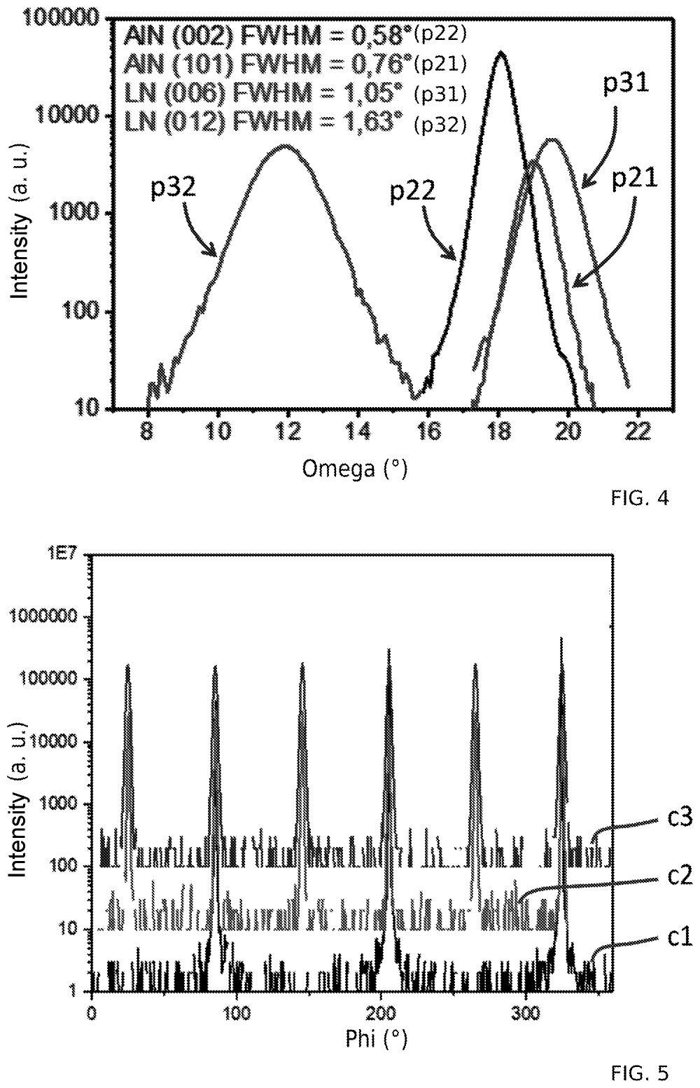

FIG. 4 illustrates a so-called “Rocking Curve” analysis performed on the stack of layers 10, 20, 30. The peak p21 corresponds to an omega scan performed around the plane (101) of the AlN. The full width at half maximum (FWHM) of this peak p21 is low, in this case around 0.58°. This indicates that the disorientation of the AlN crystallites oriented along (101) is low. The peak p22 corresponds to an omega scan performed around the plane (002) of the AlN. The full width at half maximum (FWHM) of this peak p22 is low, in this case around 0.76°. This indicates that the disorientation of the AlN crystallites oriented along (002) is low. The peak p31 corresponds to an omega scan performed around the plane (006) of the LiNbO3. The full width at half maximum (FWHM) of this peak p31 is low, in this case around 1.05°. This indicates that the disorientation of the LiNbO3 crystallites oriented along (006) is low. The peak p32 corresponds to an omega scan performed around the plane (012) of the LiNbO3.

The full width at half maximum (FWHM) of this peak p32 is low, in this case around 1.63°. This indicates that the disorientation of the LiNbO3 crystallites oriented along (012) is low.

The AlN layer 20 and the LiNbO3 layer 30 obtained by the method according to the invention are therefore actually textured.

FIG. 5 illustrates a so-called “phi-scan” analysis, performed on the stack of layers 10, 20, 30. The curve c1 corresponds to a phi scan performed for the plane (220) of the Si. The curve c2 corresponds to a phi scan performed for the plane (101) of the AlN. The curve c3 corresponds to a phi scan performed for the plane (116) of the LiNbO3. An epitaxy relationship between AlN and Si on the one hand, and between AlN and LiNbO3 on the other hand, is highlighted by the periodicity of the diffraction peaks. The AlN 20 and LiNbO3 30 layers obtained by the method according to the invention are therefore actually subjected to epitaxy.

The present invention advantageously makes it possible to form thin LN/LT layers of good crystalline quality on silicon-based substrates comprising a nucleation layer made of a nitride-based refractory material, typically material III-N-based. These thin. LN/LT layers are advantageously directly integrable in SAW resonator- or RF filter-type electroacoustic devices. Other applications can be considered. The invention is not limited to the embodiments described above.

1. A method for forming an LN/LT layer, with the basis of an ABO3 material, O being oxygen, A being at least one first chemical element taken from among sodium (Na), potassium (K), barium (Ba), lithium (Li), and lead (Pb), and B being at least one second chemical element taken from among zirconium (Zr), titanium (Ti), niobium (Nb), and tantalum (Ta), the method comprising:
providing a silicon-based substrate,
forming a nucleation layer on the substrate, and
forming the LN/LT layer by epitaxy on the nucleation layer,
wherein the nucleation layer is made of a nitride-based refractory material, and
wherein the substrate is silicon-based, oriented along (111), the nucleation layer is aluminium nitride AlN-based, oriented along (0001), and the LN/LT layer is oriented along (0001).

2. The method according to claim 1, wherein the nitride-based refractory material is taken from among III-N refractory nitrides with a basis of an element of group III, or transition refractory nitrides with a basis of a transition metal.

3. The method according to claim 2, wherein the nitride-based refractory material is a refractory nitride III-N taken from among gallium nitride GaN, aluminium nitride AlN, and AlGaN alloy.

4. The method according to claim 1, wherein the ABO3 material of the LN/LT layer is chosen from among: lithium niobate (LiNbO3), lithium tantalum (LiTaO3), or an Li(Nb,Ta)O3 alloy.

5. The method according to claim 1, wherein forming the nucleation layer comprises forming the nucleation layer to have a thickness less than or equal to 200 nm.

6. The method according to claim 1, wherein forming the LN/LT layer comprises forming the LN/LT layer to have, after epitaxy, a thickness between 50 nm and 500 nm.

7. The method according to claim 1, comprising forming the nucleation layer and forming the LN/LT layer by pulsed laser deposition successively within one same reactor without venting with air between the formings.

8. The method according to claim 1, wherein the silicon-based substrate is formed of a material taken from among: silicon, SiC, and SiGe.

9. A device comprising, in a stack in a vertical direction, a silicon-based substrate, a nucleation layer on the substrate, an LN/LT layer on the nucleation layer, the LN/LT layer being based upon a material of the ABO3 type. O being oxygen, A being at least one first chemical element taken from among sodium (Na), potassium (K), barium (Ba), lithium (Li), and lead (Pb), and B being at least one second chemical element taken from among zirconium (Zr), titanium (Ti), niobium (Nb), and tantalum (Ta), and at least one upper electrode disposed on the LN/LT layer, wherein the nucleation layer is made of a nitride-based refractory material.

10. The device according to claim 9, wherein the LN/LT layer is directly in contact with the nucleation layer.

11. The device according to claim 9, wherein the nitride-based refractory material is taken from among refractory nitrides III-N with a basis of an element of group III, or transition refractory nitrides with a basis of a transition metal.

12. The device according to claim 9, wherein the LN/LT layer has a thickness of between 50 nm and 500 nm, such that the device forms a piezoelectric thin layer resonator.

13. The device according to claim 9, further comprising, on the upper electrode and the LN/LT layer, a temperature compensation layer.

14. The device according to claim 9, wherein the silicon-based substrate is monocrystalline.

15. The method according to 1, wherein the nitride-based refractory material is taken from among
boron nitride BN, aluminium nitride AlN, gallium nitride GaN, indium nitride InN, and their alloys, and
titanium nitride TiN, tantalum nitride TaN, niobium nitride NbN, zirconium nitride ZrN, hafnium nitride HfN, and vanadium nitride VN.

16. The method according to claim 1, wherein forming the nucleation layer comprises forming the nucleation layer to have a thickness less than or equal to 50 nm.

17. The method according to claim 1, wherein forming the LN/LT layer comprises forming the LN/LT layer to have, after epitaxy, a thickness around 200 nm.
